(19) United States
(12) Patent Application Publication
(10) Pub. No.: US 2026/0005110 A1
(43) Pub. Date: Jan. 1, 2026

(54) CHIP PACKAGE STRUCTURE

(71) Applicant: TONG HSING ELECTRONIC INDUSTRIES, LTD., Taoyuan City (TW)

(72) Inventors: YU-HSIEN LIAO, Taoyuan City (TW); JIAN-YU SHIH, Taoyuan City (TW); JHIH-WEI LAI, Taoyuan City (TW); CHUN-CHIEH LIAO, Taoyuan City (TW)

(21) Appl. No.: 18/914,279

(22) Filed: Oct. 14, 2024

(30) Foreign Application Priority Data
Jun. 26, 2024 (TW) 113123671

(51) Int. Cl. H01L 23/495; H01L 23/00; H01L 23/15; H01L 23/31

(52) U.S. Cl. CPC H01L 23/49582; H01L 23/3142; H01L 23/49548; H01L 24/48; H01L 23/15; H01L 2224/48245

(57) ABSTRACT

A chip package structure includes a ceramic substrate, a copper structure, a noble metal layer, a chip, and an encapsulation gel. The copper structure is formed on the ceramic substrate, and at least one sidewall of the copper structure is recessed to form a groove. The noble metal layer is formed on the copper structure. The chip is disposed on the noble metal layer. The encapsulation gel is formed on the ceramic substrate to encapsulate the copper structure, the noble metal layer, and the chip. A surface treatment layer is formed on an exposed copper surface of the copper structure that is not in contact with the ceramic substrate and the noble metal layer, and the encapsulation gel contacts the surface treatment layer for bonding to the copper structure. The surface treatment layer extends to a surface inside the groove, and the encapsulation gel further fills the groove.

### CROSS-REFERENCE TO RELATED PATENT APPLICATION

This application claims the benefit of priority to Taiwan Patent Application No. 113123671, filed on Jun. 26, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a chip package structure.

### BACKGROUND OF THE DISCLOSURE

In conventional chip packaging technologies, to improve reliability and electrical performance of a chip package structure, a large amount of noble metal materials, such as gold (Au), silver (Ag), and palladium (Pd), are usually used. However, the high costs and limited resources of these noble metal materials lead to a significant increase in manufacturing costs. Moreover, extensive use of noble metal layers in the chip package structure also increases material waste, further elevating manufacturing costs.

A conventional chip package structure often has an issue of insufficient heterogeneous bonding strength between a copper surface and an encapsulation gel, which can lead to failure of the chip package structure under high-temperature or high-pressure environments, thereby affecting the reliability and lifespan of the chip package structure. In the related art, the heterogeneous bonding strength of the copper surface is usually enhanced through physical roughening or chemical treatment. However, these methods often require complex processes and high-cost materials.

Therefore, there is an urgent need in the relevant industry for an improved chip package structure that can reduce manufacturing costs while enhancing the reliability and design flexibility of the package.

### SUMMARY OF THE DISCLOSURE

In response to the above-referenced technical inadequacies, the present disclosure provides a chip package structure.

In order to solve the above-mentioned problems, one of the technical aspects adopted by the present disclosure is to provide a chip package structure including a ceramic substrate, a copper structure, a noble metal layer, a chip, and an encapsulation gel. The copper structure is formed on the ceramic substrate, and at least one sidewall of the copper structure is recessed to form a groove. The noble metal layer is formed on the copper structure. The chip is disposed on the noble metal layer. The encapsulation gel is formed on the ceramic substrate to encapsulate the copper structure, the noble metal layer, and the chip. A surface treatment layer is formed on an exposed copper surface of the copper structure that is not in contact with the ceramic substrate and the noble metal layer, and the encapsulation gel is bonded to the copper structure by contacting the surface treatment layer. The surface treatment layer further extends to a surface inside the groove, and the encapsulation gel fills and is engaged with the groove.

In order to solve the above-mentioned problems, another one of the technical aspects adopted by the present disclosure is to provide a chip package structure including a ceramic substrate, a copper structure, a noble metal layer, a chip, and an encapsulation gel. The copper structure is formed on the ceramic substrate. The noble metal layer is formed on the copper structure. The chip is disposed on the noble metal layer. The encapsulation gel is formed on the ceramic substrate to encapsulate the copper structure, the noble metal layer, and the chip. A surface treatment layer is formed on an exposed copper surface of the copper structure that is not in contact with the ceramic substrate and the noble metal layer, and the encapsulation gel is bonded to the copper structure by contacting the surface treatment layer. The copper structure is in the form of elongated supporting copper pillars, a quantity of supporting copper pillars is plural, the supporting copper pillars are arranged at intervals and stand upright on the ceramic substrate, and the encapsulation gel fills gaps between the plurality of supporting copper pillars.

Therefore, the chip package structure provided by the present disclosure can enhance the heterogeneous bonding strength between the encapsulation gel and the copper structure by virtue of “a surface treatment layer being formed on the exposed copper surface of the copper structure that is not in contact with the ceramic substrate and the noble metal layer, and the encapsulation gel being bonded to the copper structure by contacting the surface treatment layer” and “the grooves being formed on the sidewalls of the copper structure or the copper structure including plurality of supporting copper pillars.” Additionally, this design can reduce the use of noble metals.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a side view of a chip package structure according to a first embodiment of the present disclosure;

FIG. 2 is a partially enlarged view of area II of FIG. 1;

FIG. 3 is a top view of the chip package structure according to the first embodiment of the present disclosure;

FIGS. 4A to 4H are schematic flow diagrams of a manufacturing method of the chip package structure according to the first embodiment of the present disclosure;

FIG. 5 is a side view of a chip package structure according to a second embodiment of the present disclosure;

FIG. 6A is a top view of the chip package structure according to the second embodiment of the present disclosure;

FIG. 6B is a bottom view of the chip package structure according to the second embodiment of the present disclosure;

FIG. 7 is a schematic view the chip package structure in another configuration according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

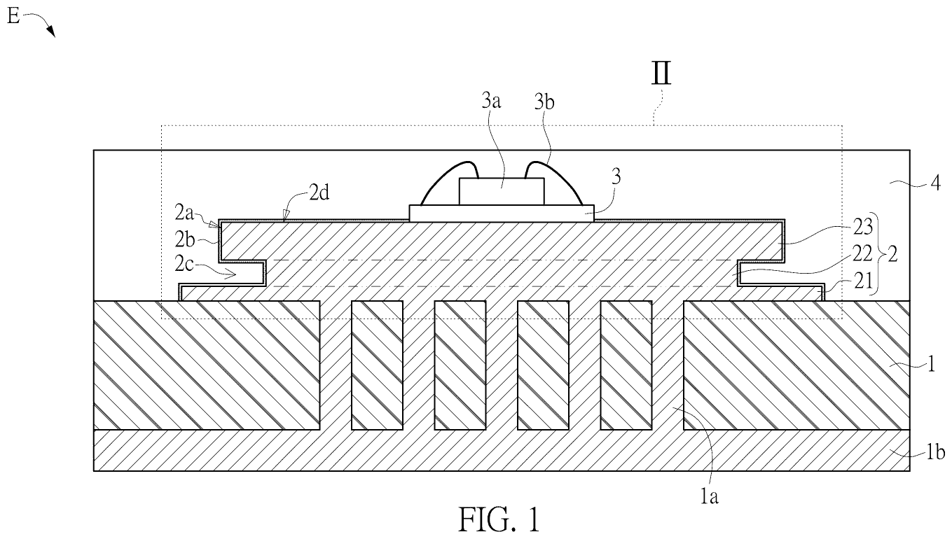

Referring to FIGS. 1 to 3, a first embodiment of the present disclosure provides a chip package structure E, particularly related to a chip package structure E based on an eDPC stack (Embedded Dual-side Plated Copper stack).

An objective of the first embodiment of the present disclosure is to reduce an area of a noble metal on the eDPC stack, increase an exposed copper surface area on the surface and sidewalls of the eDPC stack, and form a surface treatment layer on the exposed copper surface to enhance a heterogeneous bonding strength between an encapsulation gel and the copper surface. Additionally, the chip package structure E of the first embodiment of the present disclosure can increase the heterogeneous bonding strength of the copper surface without affecting the reliability of the noble metal surface bonding, and also provides a solder mask effect.

To achieve the above objective, the chip package structure E includes a ceramic substrate 1, a copper structure 2, a noble metal layer 3, a chip 3a, at least one wire 3b (e.g., lead wire), and an encapsulation gel 4.

The copper structure 2 is formed on a side surface (e.g., a top surface) of the ceramic substrate 1. The noble metal layer 3 is formed on a side surface (e.g., a top surface 2d) of the copper structure 2 away from the ceramic substrate 1. The chip 3a is disposed on a side surface of the noble metal layer 3 away from the copper structure 2. The at least one wire 3b is connected between a top surface of the chip 3a and a top surface of the noble metal layer 3.

Furthermore, the encapsulation gel 4 is formed on the side surface of the ceramic substrate 1, and encapsulates the copper structure 2, the noble metal layer 3, the chip 3a, and the wire 3b. That is, the copper structure 2, the noble metal layer 3, the chip 3a, and the wire 3b are encapsulated inside and covered by the encapsulation gel 4.

In some embodiments of the present disclosure, the ceramic substrate 1 can be made of materials such as aluminum nitride (AlN), aluminum oxide (Al₂O₃), silicon nitride (SiN), or silicon carbide (SiC).

Furthermore, an inside of the ceramic substrate 1 has at least one through-hole copper pillar 1a that penetrates a top surface and a bottom surface thereof, and the bottom surface of the ceramic substrate 1 is formed with a bottom copper layer 1b. The at least one through-hole copper pillar 1a is electrically connected between the copper structure 2 and the bottom copper layer 1b. In the present embodiment, a quantity of through-hole copper pillar 1a is plural, and a plurality of through-hole copper pillars 1a are arranged at intervals. The bottom copper layer 1b substantially covers the bottom surface of the ceramic substrate 1, but the present disclosure is not limited thereto.

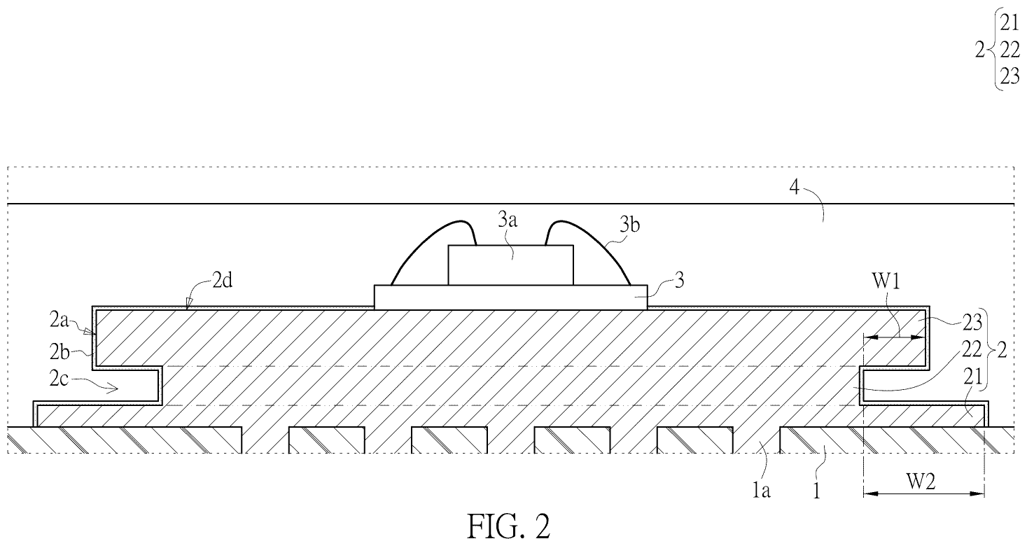

Further referring to FIGS. 1 and 2, a surface treatment layer 2b is formed on an exposed copper surface of the copper structure 2 that is not in contact with the ceramic substrate 1 and the noble metal layer 3. The encapsulation gel 4 is bonded to the copper structure 2 through the surface treatment layer 2b to enhance the heterogeneous bonding strength between the encapsulation gel 4 and the copper structure 2. In the present embodiment, the surface treatment layer 2b is formed on at least one sidewall 2a of the copper structure 2 that is not in contact with the ceramic substrate 1 and the noble metal layer 3, and is partially formed on the top surface 2d of the copper structure 2 that is connected to the sidewall 2a. Additionally, the top surface of the noble metal layer 3 is not formed with the surface treatment layer 2b, so as to increase the heterogeneous bonding strength of the copper surface without affecting the reliability of the noble metal surface bonding.

The surface treatment layer 2b can be, for example, a roughened surface treatment layer, and a surface roughness (e.g., arithmetic average roughness Ra) of the roughened surface treatment layer is greater than a surface roughness of the noble metal layer 3, but the present disclosure is not limited thereto.

In another embodiment of the present disclosure, the surface treatment layer 2b can also be a functionalized surface treatment layer, which can be, for example, a surface treatment layer with silane functional groups and/or siloxane functional groups. In yet another embodiment of the present disclosure, the surface treatment layer 2b can also be a chemically bonded surface treatment layer, which can be, for example, an oxidized copper (CuO) surface treatment layer, but the present disclosure is not limited thereto.

Furthermore, in the present embodiment, a groove 2c is recessed inside the sidewall 2a of the copper structure 2, the surface treatment layer 2b extends to cover a surface inside the groove 2c, and the encapsulation gel 4 further fills the groove 2c of the copper structure 2 and contacts the surface treatment layer 2b inside the groove 2c.

Since the encapsulation gel 4 is filled into the groove 2c of the copper structure 2, an engaged structure where the encapsulation gel 4 and the copper structure 2 are engaged to each other can be formed, so as to increase the contact area between the encapsulation gel 4 and the copper structure 2, thereby enhancing the bonding strength between the encapsulation gel 4 and the copper structure 2.

In the present embodiment, the noble metal layer 3 is formed on the top surface 2d of the copper structure 2, and an occupied area of the noble metal layer 3 is less than an occupied area of the top surface 2d of the copper structure 2.

In other words, the noble metal layer 3 is merely formed on a portion of the top surface 2d of the copper structure 2, which enables at least another portion of the top surface 2d of the copper structure 2 to be exposed and covered by the surface treatment layer 2b.

According to the above configuration, the chip package structure E provided by the embodiment of the present disclosure can reduce the occupied area of the noble metal in the eDPC stack, increase the exposed copper surface area on the surface and sidewalls 2a of the copper structure 2, and enhance the heterogeneous bonding strength between the encapsulation gel 4 and the copper surface of the copper structure 2 by forming the surface treatment layer 2b on the exposed copper surface. Additionally, the heterogeneous bonding strength of the copper surface can be increased without affecting the reliability of the noble metal surface bonding.

More specifically, reference is made FIG. 2, which is a partially enlarged side view of the copper structure 2 of the embodiment of the present disclosure. The copper structure 2 includes a first copper layer 21, a second copper layer 22, and a third copper layer 23 sequentially stacked on the side surface (i.e., the top surface) of the ceramic substrate 1. A sidewall of the second copper layer 22 is recessed relative to a sidewall of the first copper layer 21 and is recessed relative to a sidewall of the third copper layer 23, thereby forming the groove 2c that is recessed inside the sidewall 2a of the copper structure 2.

In other words, the sidewall of the third copper layer 23 protrudes relative to the sidewall of the second copper layer 22, so as to form a roof structure, and a length that the sidewall of the third copper layer 23 protrudes relative to the sidewall of the second copper layer 22 is defined as a first protruding length W1. Additionally, the sidewall of the first copper layer 21 also protrudes relative to the sidewall of the second copper layer 22, and a length that the sidewall of the first copper layer 21 protrudes relative to the sidewall of the second copper layer 22 is defined as a second protruding length W2.

The first protruding length W1 is smaller than the second protruding length W2, and the first protruding length W1 is not greater than 50 micrometers, and is preferably between 15 micrometers and 50 micrometers.

Accordingly, the groove 2c can have sufficient space to enable the encapsulation gel 4 to more stably interlock with the groove 2c of the copper structure 2, thereby enhancing the bonding strength, but is not limited thereto.

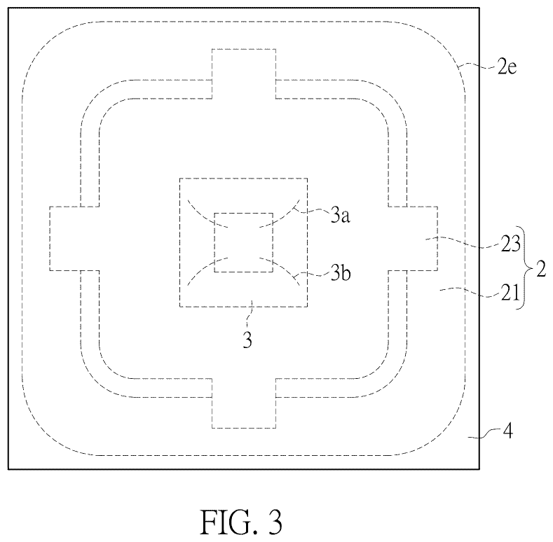

Referring to FIG. 3, FIG. 3 is a top view of the chip package structure E of the embodiment of the present disclosure. In the copper structure 2, the roof structure of the sidewall of the third copper layer 23 protruding relative to the sidewall of the second copper layer 22 can be rectangular, but the present disclosure is not limited thereto. The protruding shape of the third copper layer 23 can also be semicircular, triangular, or other physical shapes.

Additionally, a quantity of the roof structure protruding from the third copper layer 23 can be, for example, four. The four roof structures are located on four corner edges of the third copper layer 23, and each two of the roof structures are opposite to another two of the roof structures.

Furthermore, four corner edges of the first copper layer 21 can be designed as rounded edges 2e, which can replace traditional right-angle designs, so as to reduce stress concentration, preventing the copper layer from peeling off or warping from the ceramic substrate.

Further referring to FIG. 1, the noble metal layer 3 is formed on a side surface of the copper structure 2 away from the ceramic substrate 1 (e.g., the top surface 2d of the third copper layer 23). A thickness of the noble metal layer 3 is less than an overall thickness of the copper structure 2 (i.e., a total thickness of the first copper layer 21, the second copper layer 22, and the third copper layer 23), and the thickness of the noble metal layer 3 is not greater than one-third of the overall thickness of the copper structure 2, but the present disclosure is not limited thereto.

A material of the noble metal layer 3 can include at least one of gold (Au), silver (Ag), palladium (Pd), and nickel (Ni), and the noble metal layer 3 can be formed by electroplating, electroless plating, physical vapor deposition (PVD), or chemical vapor deposition (CVD).

In some embodiments of the present disclosure, the noble metal layer 3 can be electroplated nickel-palladium-gold, electroplated ultra-thin nickel-palladium-gold (e.g., Ni<3 um, Pd<0.076 um, Au<0.076 um), electroplated nickel-gold, electroplated nickel-silver, electroplated nickel, electroless nickel-palladium-gold, electroless ultra-thin nickel-palladium-gold (Ni<0.25 um, Pd<0.12 um, Au<0.07 um), electroless nickel-gold, electroless silver, electroless nickel, PVD titanium-platinum-gold (PVD Ti/Pt/Au), or PVD gold-tin (PVD Au/Sn).

Furthermore, a material of the encapsulation gel 4 can be at least one of epoxy resin, polyimide resin, silicone resin, and polyurethane resin, and is preferably epoxy resin.

According to the above configuration, the chip package structure E of the embodiment of the present disclosure can have better reliability, avoiding issues with wire bonding or poor soldering quality due to excessive roughness of the noble metal layer 3 surface treatment.

Additionally, the heterogeneous bonding strength between the copper surface and the encapsulation gel can be increased, and the copper surface sidewall can also have increased bonding strength (better than general physical roughening). Moreover, the chip package structure E of the embodiment of the present disclosure does not require full-surface noble metal treatment, resulting in lower manufacturing costs.

Furthermore, the chip package structure E of the embodiment of the present disclosure can have a flexible design with different exposed copper surface areas and shapes according to product design needs.

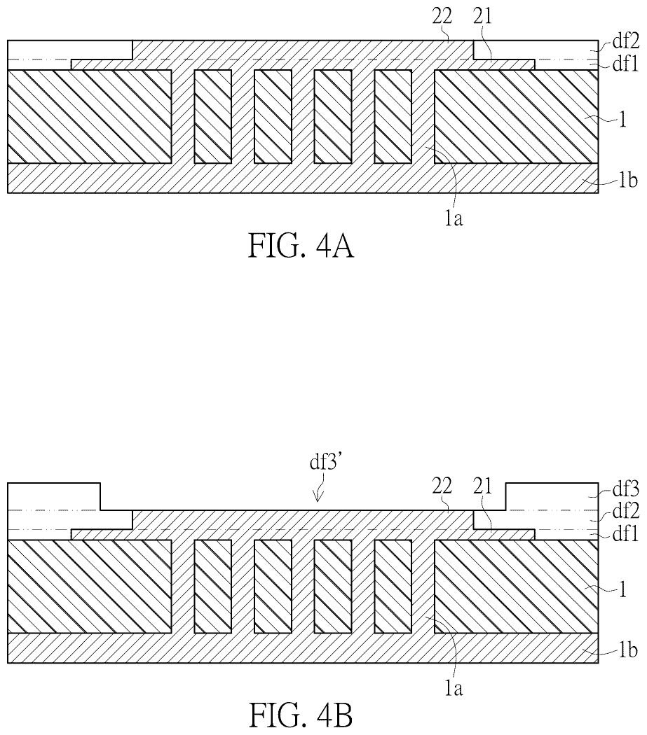

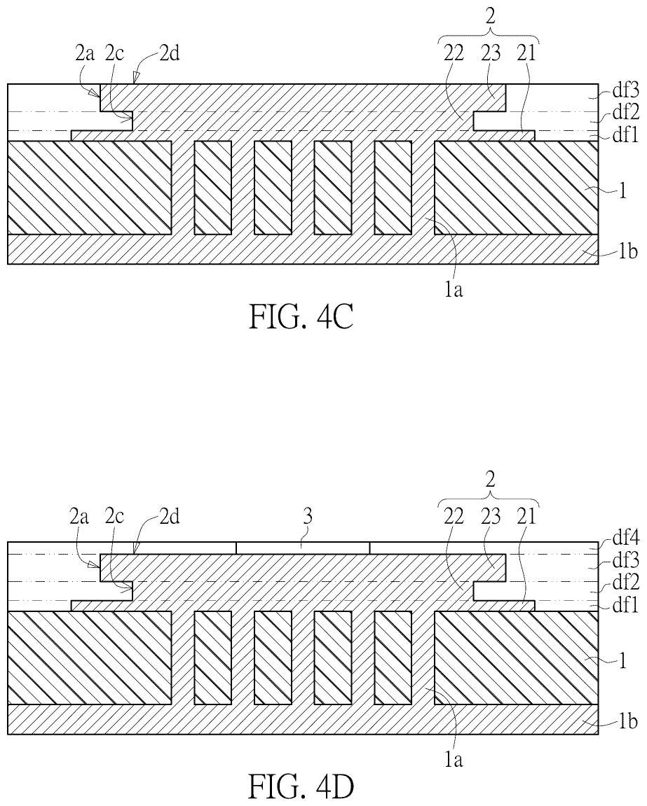

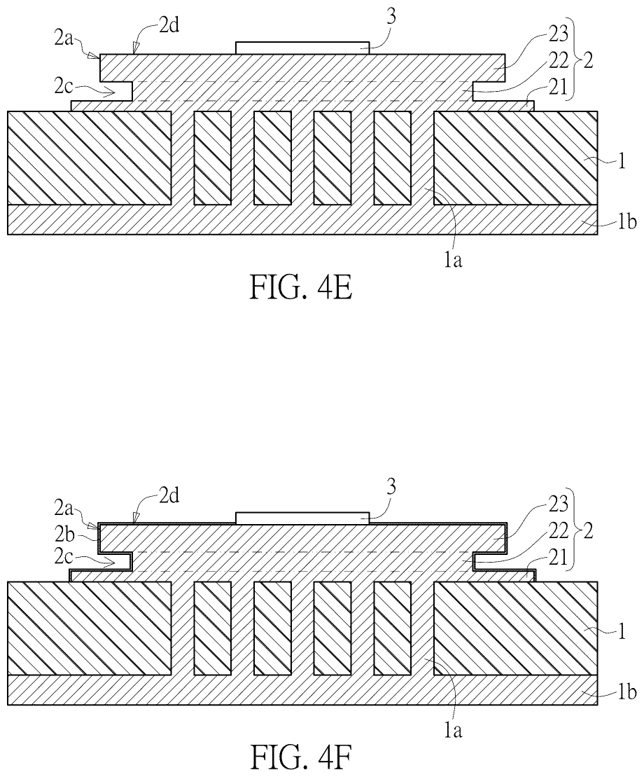

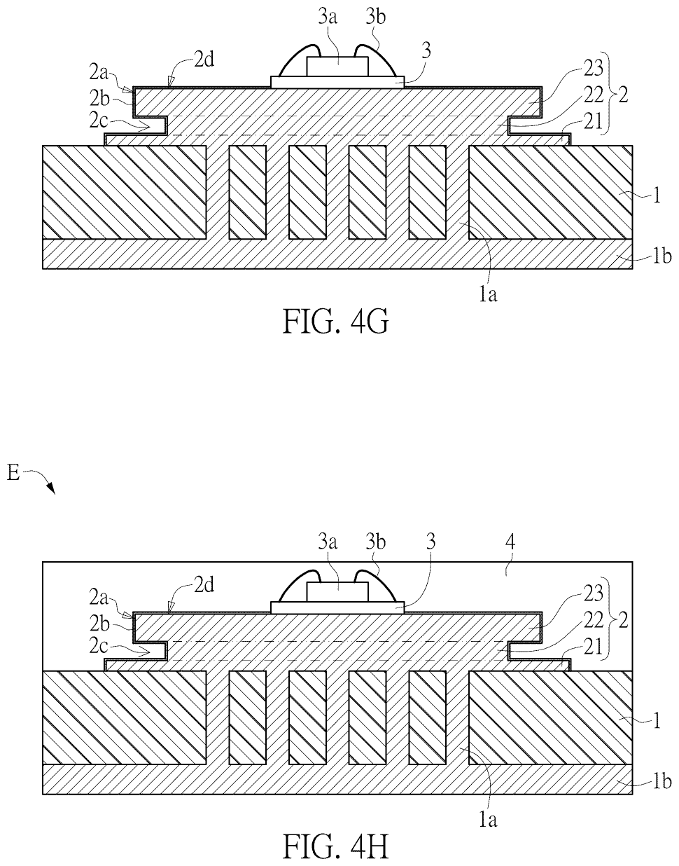

Reference is made to FIGS. 4A to 4H, which illustrate a manufacturing method of the chip package structure E of the first embodiment of the present disclosure. However, the chip package structure E of the present disclosure is not limited to being manufactured by this method. The manufacturing method of the chip package structure includes steps S110, S120, S130, S140, S150, S160, S170, and S180.

As shown in FIG. 4A, step S110 is to perform a ceramic substrate copper cladding operation, which includes providing a ceramic substrate 1 and sequentially forming a first copper layer 21 and a second copper layer 22 on a top surface of the ceramic substrate 1 through a photolithography process with a first photoresist film df1 and a second photoresist film df2.

At least one through-hole copper pillar 1a is formed in an inside of the ceramic substrate 1, and a bottom copper layer 1b is formed on a bottom surface of the ceramic substrate 1. The through-hole copper pillar 1a is electrically connected between the first copper layer 21 and the bottom copper layer 1b.

As shown in FIG. 4B, step S120 is to form a third photoresist film df3 on the second photoresist film df2, and to form a film removal space df3′ inside the third photoresist film df3 that is positioned above the second copper layer 22.

As shown in FIG. 4C, step S130 is to form a third copper layer 23 (e.g., by electroplating) on the second copper layer 22, so that the first copper layer 21, the second copper layer 22, and the third copper layer 23 together form a copper structure 2. A sidewall of the second copper layer 22 is recessed relative to a sidewall of the first copper layer 21 and a sidewall of the third copper layer 23, thereby forming a groove 2c on the sidewall 2a of the copper structure 2. In addition, a roof structure formed by the sidewall of the third copper layer 23 protruding relative to the sidewall of the second copper layer 22 can increase the exposed surface area of the copper surface.

As shown in FIG. 4D, step S140 is to form a fourth photoresist film df4 on the third photoresist film df3, and to form a noble metal layer 3 inside the fourth photoresist film df4, in which the noble metal layer 3 is connected above the third copper layer 23 and partially covers the top surface 2d of the third copper layer 23.

As shown in FIG. 4E, step S150 is to perform a photoresist removal operation to remove the first photoresist film df1, the second photoresist film df2, the third photoresist film df3, and the fourth photoresist film df4 from the ceramic substrate 1, thereby exposing the copper structure 2 (including the first copper layer 21, the second copper layer 22, and the third copper layer 23) and the noble metal layer 3 to an external environment.

As shown in FIG. 4F, step S160 is to perform a surface treatment operation to form a surface treatment layer 2b on an exposed copper surface of the copper structure 2 that is not in contact with the ceramic substrate 1 and the noble metal layer 3.

In the present embodiment, the surface treatment layer 2b is formed on the sidewall 2a of the copper structure 2 that is not in contact with the ceramic substrate 1 and the noble metal layer 3, partially formed on the top surface 2d of the copper structure 2 connected to the sidewall 2a, and further extended to the surface inside the groove 2c. In addition, the top surface and sidewalls of the noble metal layer 3 are not formed with the surface treatment layer 2b to increase the heterogeneous bonding strength of the copper surface without affecting the reliability of the noble metal surface bonding.

It is worth mentioning that the surface treatment operation of step S160 can be performed directly on the exposed copper surface of the copper structure 2 without additional protection for the noble metal layer 3, thereby simplifying the manufacturing process, but the present disclosure is not limited thereto.

As shown in FIG. 4G, step S170 is to place a chip 3a on a top surface of the noble metal layer 3 that is away from the copper structure 2, and to connect at least one wire 3b between the top surface of the chip 3a and the top surface of the noble metal layer 3.

As shown in FIG. 4H, step S180 is to perform an encapsulation operation, which includes forming an encapsulation gel 4 on the ceramic substrate 1 to encapsulate the copper structure 2, the noble metal layer 3, the chip 3a, and the wire 3b, so as to form a chip package structure E. The encapsulation gel 4 contacts the surface treatment layer 2b, fills the groove 2c, and is engaged with the copper structure 2, thereby enhancing the heterogeneous bonding strength between the encapsulation gel 4 and the copper structure 2.

### Second Embodiment

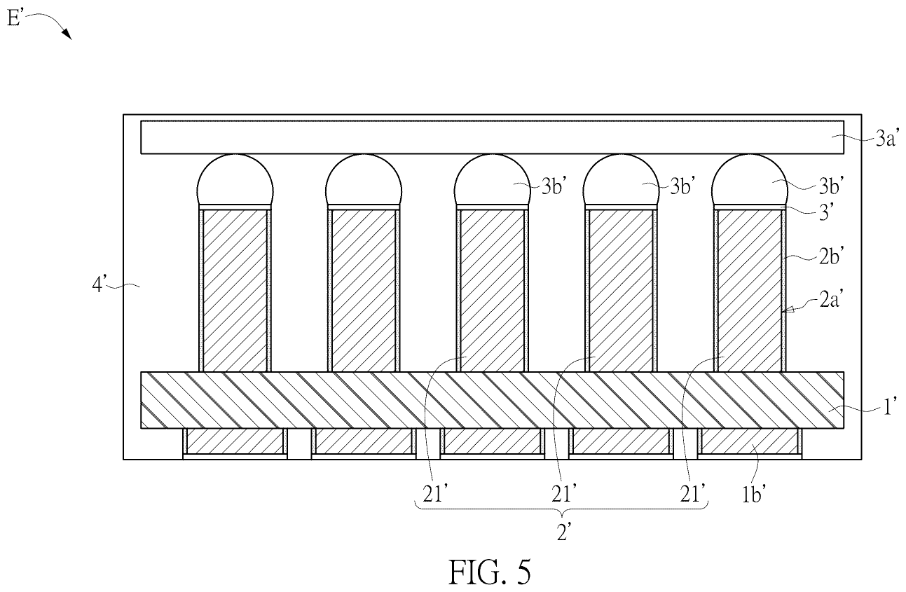

Referring to FIGS. 5 to 7, a second embodiment of the present disclosure provides a chip package structure E′, which can be applied to a chip packaging based on copper pillars or RDL stacking.

An objective of the second embodiment of the present disclosure is to increase the exposed copper surface area on the surface and sidewalls of a copper structure and form a surface treatment layer on the exposed copper surface to enhance the heterogeneous bonding strength between the encapsulation gel and the copper surface.

To achieve the above objective, as shown in FIG. 5, the chip package structure E′ of the second embodiment of the present disclosure includes a ceramic substrate 1′, at least one copper structure 2′, at least one noble metal layer 3′, a chip 3a′, at least one solder ball 3b′, and an encapsulation gel 4′.

The copper structure 2′ is formed on a side surface (e.g., the top surface) of the ceramic substrate 1′. The noble metal layer 3′ is formed on a side surface (e.g., the top surface) of the copper structure 2′ away from the ceramic substrate 1′. The chip 3a′ is disposed on a side surface of the noble metal layer 3′ away from the copper structure 2′ through the solder ball 3b′. The encapsulation gel 4′ is formed on the ceramic substrate 1′ to encapsulate the copper structure 2′, the noble metal layer 3′, the chip 3a′, and the solder ball 3b′. Furthermore, a bottom surface of the ceramic substrate 1′ is formed with at least one bottom copper pad 1b′, but the present disclosure is not limited thereto.

Referring to FIG. 5 again, a surface treatment layer 2b′ is formed on the exposed copper surface of the copper structure 2′ that is not in contact with the ceramic substrate 1′ and the noble metal layer 3′. The encapsulation gel 4′ is bonded to the copper structure 2′ by contacting the surface treatment layer 2b′ to enhance the heterogeneous bonding strength between the encapsulation gel 4′ and the copper structure 2′.

In the present embodiment, the surface treatment layer 2b′ is formed on at least one sidewall 2a′ of the copper structure 2′ that is not in contact with the ceramic substrate 1′ and the noble metal layer 3′.

The surface treatment layer 2b′ can be, for example, one of a roughened surface treatment layer, a functionalized surface treatment layer, or a chemically bonded surface treatment layer.

More specifically, in the present embodiment, the copper structure 2′ is in a form of elongated supporting copper pillars 21′, and a quantity of the supporting copper pillars 21′ is multiple (plural).

A plurality of supporting copper pillars 21′ are arranged at intervals and stand upright on the ceramic substrate 1′. Correspondingly, the quantity of the noble metal layers 3′, the solder balls 3b′, and the bottom copper pads 1b′ are also multiple (plural).

In other words, the plurality of noble metal layers 3′ are respectively formed on the plurality of supporting copper pillars 21′, the plurality of solder balls 3b′ are respectively formed on the plurality of noble metal layers 3′, and the chip 3a′ is disposed on the ceramic substrate 1′ through the plurality of supporting copper pillars 21′, the noble metal layers 3′, and the solder balls 3b′.

Additionally, the plurality of bottom copper pads 1b′ are positioned corresponding to the plurality of supporting copper pillars 21′ relative to the bottom of the ceramic substrate 1′ to be electrically connected to each other, but the present disclosure is not limited thereto.

In the present embodiment, the surfaces of the sidewalls 2a′ of the plurality of supporting copper pillars 21′ are formed with the surface treatment layer 2b′, and the encapsulation gel 4′ further fills the gaps between the plurality of supporting copper pillars 21′ and contacts the surface treatment layer 2b′, thereby increasing the contact area between the encapsulation gel 4′ and the supporting copper pillars 21′, and enhancing the heterogeneous bonding strength between the encapsulation gel 4′ and the copper surface.

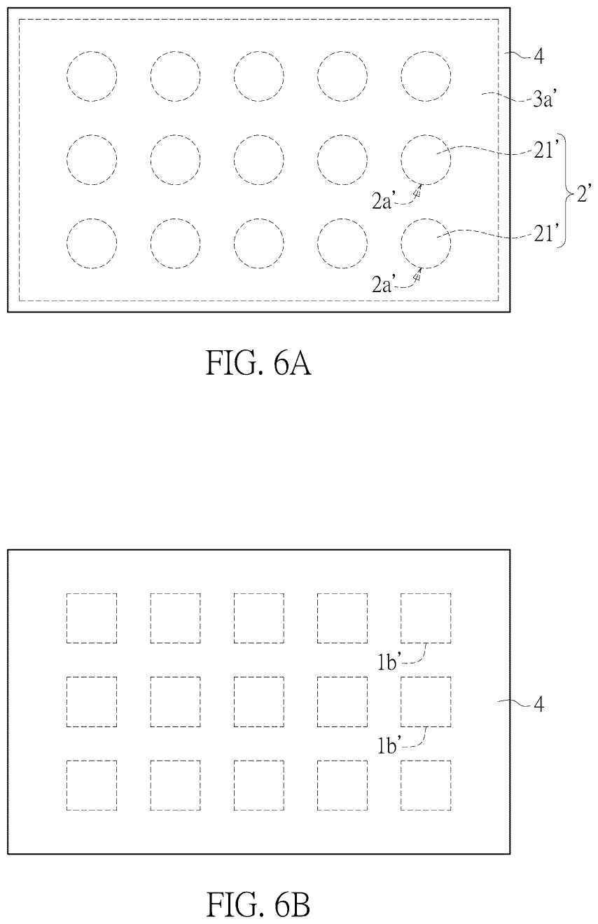

FIG. 6A is a top schematic view of the chip package structure E′ of the present embodiment, showing the arrangement of the plurality of supporting copper pillars 21′, and FIG. 6B is a bottom schematic view of the chip package structure E′ of the present embodiment, showing the arrangement of the plurality of bottom copper pads 1b′, but are not limited thereto.

According to the above configuration, the chip package structure E′ of the second embodiment of the present disclosure can increase the heterogeneous bonding strength between the encapsulation gel 4′ and the copper structure 2′ by forming a surface treatment layer 2b′ on the exposed copper surface of the copper structure 2′ that is not in contact with the ceramic substrate l′ and the noble metal layer 3′, and bonding the encapsulation gel 4′ to the copper structure 2′ through being contact with the surface treatment layer 2b′.

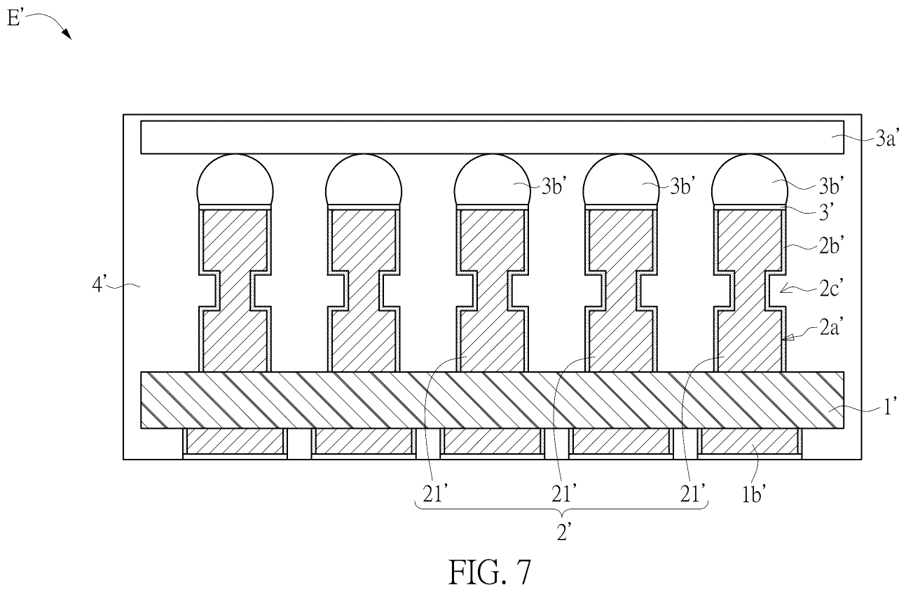

Reference is made to FIG. 7, which is a schematic view of the chip package structure E′ in another configuration according to the second embodiment of the present disclosure. In the chip package structure E′ shown in FIG. 7, the sidewall 2a′ of each of the supporting copper pillars 21′ are recessed to form at least one groove 2c′, and the surface treatment layer 2b′ is extended to the surface inside the groove 2c′, and the encapsulation gel 4′ further fills the groove 2c′ of the supporting copper pillar 21′ and contacts the surface treatment layer 2b′ inside the groove 2c′.

Since the encapsulation gel 4′ fills the groove 2c′, an engaged structure is formed between the encapsulation gel 4′ and the supporting copper pillar 21′, increasing the contact area between the encapsulation gel 4′ and the copper structure 2′, thereby enhancing the heterogeneous bonding strength between the encapsulation gel 4′ and the copper structure 2′.

### Beneficial Effects of the Embodiments

In conclusion, the chip package structure provided by the present disclosure can enhance the heterogeneous bonding strength between the encapsulation gel and the copper structure by virtue of “a surface treatment layer being formed on the exposed copper surface of the copper structure that is not in contact with the ceramic substrate and the noble metal layer, and the encapsulation gel being bonded to the copper structure by contacting the surface treatment layer” and “the grooves being formed on the sidewalls of the copper structure or the copper structure including plurality of supporting copper pillars.” Additionally, this design can reduce the use of noble metals.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A chip package structure, comprising:
a ceramic substrate;
a copper structure formed on the ceramic substrate, wherein at least one sidewall of the copper structure is recessed to form a groove;
a noble metal layer formed on the copper structure;
a chip disposed on the noble metal layer; and
an encapsulation gel formed on the ceramic substrate to encapsulate the copper structure, the noble metal layer, and the chip;
wherein a surface treatment layer is formed on an exposed copper surface of the copper structure that is not in contact with the ceramic substrate and the noble metal layer, and the encapsulation gel is bonded to the copper structure by contacting the surface treatment layer; wherein the surface treatment layer further extends to a surface inside the groove, and the encapsulation gel fills and is engaged with the groove.

2. The chip package structure according to claim 1, wherein the noble metal layer is formed on a top surface of the copper structure, and an area occupied by the noble metal layer is smaller than an area of the top surface of the copper structure.

3. The chip package structure according to claim 1, further comprising:
at least one wire connected between a top surface of the chip and a top surface of the noble metal layer;
wherein the surface treatment layer is formed on at least one sidewall of the copper structure that is not in contact with the ceramic substrate and the noble metal layer, and partially formed on a top surface of the copper structure connected to the sidewall, and the surface treatment layer is not formed on the top surface of the noble metal layer.

4. The chip package structure according to claim 1, wherein the copper structure includes: a first copper layer, a second copper layer, and a third copper layer sequentially formed on the ceramic substrate; wherein a sidewall of the second copper layer is recessed relative to sidewalls of the first copper layer and the third copper layer, so as to form the groove.

5. The chip package structure according to claim 4, wherein, in the copper structure, a length that the sidewall of the third copper layer protrudes relative to the sidewall of the second copper layer is defined as a first protruding length, and a length that the sidewall of the first copper layer protrudes relative to the sidewall of the second copper layer is defined as a second protruding length; wherein the first protruding length is smaller than the second protruding length.

6. The chip package structure according to claim 5, wherein the first protruding length is not greater than 50 micrometers.

7. The chip package structure according to claim 4, wherein four corner edges of the first copper layer are rounded edges.

8. The chip package structure according to claim 1, wherein the surface treatment layer is a roughened surface treatment layer, and a surface roughness of the roughened surface treatment layer is greater than a surface roughness of the noble metal layer.

9. The chip package structure according to claim 1, wherein the surface treatment layer is a functionalized surface treatment layer having silane functional groups and/or siloxane functional groups.

10. The chip package structure according to claim 1, wherein the surface treatment layer is a chemically bonded surface treatment layer having oxidized copper (CuO).

11. A chip package structure, comprising:
a ceramic substrate;
a copper structure formed on the ceramic substrate;
a noble metal layer formed on the copper structure;
a chip disposed on the noble metal layer; and
an encapsulation gel formed on the ceramic substrate to encapsulate the copper structure, the noble metal layer, and the chip;
wherein a surface treatment layer is formed on an exposed copper surface of the copper structure that is not in contact with the ceramic substrate and the noble metal layer, and the encapsulation gel is bonded to the copper structure by contacting the surface treatment layer;
wherein the copper structure is in the form of elongated supporting copper pillars, a quantity of supporting copper pillars is plural, and the supporting copper pillars are arranged at intervals and stand upright on the ceramic substrate, and the encapsulation gel fills gaps between the plurality of supporting copper pillars.

12. The chip package structure according to claim 11, wherein a surface of the sidewall of each of the supporting copper pillars is formed with the surface treatment layer.

13. The chip package structure according to claim 12, wherein the sidewall of each of the supporting copper pillars is recessed to form at least one groove, the surface treatment layer further extends to a surface inside the groove, and the encapsulation gel further fills the groove.
